(19) United States
(12) Patent Application Publication
(10) Pub. No.: US 2017/0243755 A1
(43) Pub. Date: Aug. 24, 2017

(54) METHOD AND SYSTEM FOR ATOMIC LAYER ETCHING

(71) Applicant: Tokyo Electron Limited, Tokyo (JP)

(72) Inventor: Kandabara N. Tapily, Mechanicville, NY (US)

(21) Appl. No.: 15/440,268

(22) Filed: Feb. 23, 2017

Related U.S. Application Data
(60) Provisional application No. 62/298,677, filed on Feb. 23, 2016.

(51) Int. Cl. H01L 21/311

(52) U.S. Cl. CPC H01L 21/31116

(57) ABSTRACT

Embodiments of the invention provide a method for atomic layer etching (ALE) of a substrate. According to one embodiment, the method includes providing a substrate, and alternatingly exposing the substrate to a fluorine-containing gas and an aluminum-containing gas to etch the substrate. According to one embodiment, the method includes providing a substrate containing a metal oxide film, exposing the substrate to a fluorine-containing gas to form a fluorinated layer on the metal oxide film, and thereafter, exposing the substrate to an aluminum-containing gas to remove the fluorinated layer from the metal oxide film. The exposing steps may be alternatingly repeated at least once to further etch the metal oxide film.

This application is related to and claims priority to U.S. provisional application Ser. No. 62/298,677 filed on Feb. 23, 2016, the entire contents of which are herein incorporated by reference.

### FIELD OF INVENTION

The present invention relates to the field of semiconductor manufacturing and semiconductor devices, and more particularly, to atomic layer etching (ALE) of thin films.

### BACKGROUND OF THE INVENTION

As device feature size continues to scale it is becoming a significant challenge to accurately control etching of fine features. For highly scaled nodes 10 nm and below, devices require atomic scaled fidelity or very tight process variability. There is significant impact on device performance due to variability. In this regards, self-limiting and atomic scale processing methods such as ALE are becoming a necessity.

### SUMMARY OF THE INVENTION

Embodiments of the invention provide a method for ALE of a substrate or a thin film on a substrate. According to one embodiment, the method includes providing a substrate, and alternatingly exposing the substrate to a fluorine-containing gas and an aluminum-containing gas to etch the substrate.

According to one embodiment, the method includes providing a substrate containing a metal oxide film, exposing the substrate to a fluorine-containing gas to form a fluorinated layer on the metal oxide film, and thereafter, exposing the substrate to an aluminum-containing gas to remove the fluorinated layer from the metal oxide film. The exposing steps may be alternatingly repeated at least once to further etch the metal oxide film.

According to one embodiment, the method includes arranging substrates containing a metal oxide film on a plurality of substrate supports in a process chamber, where the process chamber contains processing spaces defined around an axis of rotation in the process chamber, rotating the plurality of substrate supports about the axis of rotation, exposing the substrates in a first processing space a fluorine-containing gas to form a fluorinated layer on the metal oxide film, the first processing space defined by a first included angle about the axis of rotation, and exposing the substrates to an inert atmosphere within a second processing space defined by a second included angle about the axis of rotation. The method further includes exposing the substrates in a third processing space to an aluminum-containing gas to remove the fluorinated layer from the metal oxide film, the third processing space defined by a third included angle about the axis of rotation and separated from the first processing space by the second processing space, exposing the substrates to an inert atmosphere within a fourth processing space defined by a fourth included angle about the axis of rotation and separated from the second processing space by the third processing space, and re-exposing the substrates to the fluorine-containing gas and the aluminum-containing gas by repeatedly rotating the substrates through the first, second, third, and fourth processing spaces for incrementally etching the metal oxide film on each of the substrates.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a process flow diagram for processing a substrate according to an embodiment of the invention;

FIG. 2 is a process flow diagram for processing a substrate according to an embodiment of the invention;

FIGS. 3A-3D schematically show through cross-sectional views a method of processing a substrate according to an embodiment of the invention;

FIG. 4 is a process flow diagram for processing a substrate according to an embodiment of the invention;

FIG. 5 schematically shows a processing system for processing a substrate according to an embodiment of the invention;

FIG. 6 schematically shows a processing system for processing a substrate according to an embodiment of the invention;

FIG. 7 schematically shows a processing system for processing a substrate according to an embodiment of the invention; and

FIG. 8 shows etching of Al₂O₃ films by ALE according to an embodiment of the invention.

### DETAILED DESCRIPTION OF SEVERAL EMBODIMENTS

Developing advanced technology for advanced semiconductor technology nodes presents an unprecedented challenge for manufacturers of semiconductor devices, where these devices will require atomic-scale manufacturing control of etch variability. ALE is viewed by the semiconductor industry as an alternative to conventional continuous etching. ALE is a substrate processing technique that removes thin layers of material using sequential self-limiting reactions and is considered one of the most promising techniques for achieving the required control of etch variability necessary in the atomic-scale era.

ALE is defined as a film etching technique that uses sequential self-limiting reactions. The concept is analogous to atomic layer deposition (ALD), except that removal occurs in place of a second adsorption step, resulting in layer-by-layer material removal instead of addition. The simplest ALE implementation consists of two sequential steps: surface modification (1) and removal (2). Modification forms a thin reactive layer with a well-defined thickness that is subsequently more easily removed than the unmodified material. The layer is characterized by a sharp gradient in chemical composition and/or physical structure of the outermost layer of a material. The removal step takes away at least a portion of the modified layer while keeping the underlying substrate intact, thus “resetting” the surface to a suitable state for the next etching cycle. The total amount of material removed is determined by the number of repeated cycles.

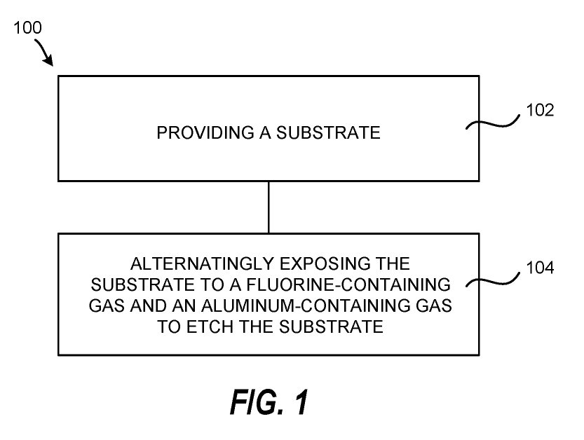

Embodiments of the invention provide a method for manufacturing of semiconductor devices, and more particularly, to ALE using a fluorine-containing gas and an aluminum-containing gas. Those skilled in the art will readily appreciate that the methods and apparatuses that are described may be used for other etching gases and thin films. FIG. 1 is a process flow diagram for processing a substrate according to an embodiment of the invention. The process flow 100 includes, in 102, providing a substrate, and in 104, alternatingly exposing the substrate to fluorine-containing gas and an aluminum-containing gas to etch the substrate or a film on the substrate. The substrate may be heated to a temperature between 100° C. and 400° C., for example. The alternating exposures are performed in the absence of plasma excitation and may be repeated at least once to further etch the substrate. According to one embodiment, the substrate contains a metal oxide film that is etched by the alternating exposures. For example, the fluorine-containing gas may be selected from hydrogen fluoride (HF) and nitrogen trifluoride (NF₃). In one example, the aluminum-containing gas can contain an organic aluminum compound. In one example, the aluminum-containing gas may be selected from the group consisting of AlMe₃, AlEt₃, AlMe₂H, [Al(O-s-Bu)₃]₄, Al(CH₃COCHCOCH₃)₃, AlCl₃, AlBr₃, AlI₃, Al(O-i-Pr)₃, [Al(NMe₂)₃]₂, Al(i-Bu)₂Cl, Al(i-Bu)₃, Al(i-Bu)₂H, AlEt₂Cl, Et₃Al₂(O-s-Bu)₃, H₃AlNMe₃, H₃AlNEt₃, H₃AlNMe₂Et, and H₃AlMeEt₂. The metal oxide film may be selected from the group consisting of Al₂O₃, HfO₂, TiO₂, ZrO₂, Y₂O₃, La₂O₃, UO₂, Lu₂O₃, Ta₂O₅, Nb₂O₅, ZnO, MgO, CaO, BeO, V₂O₅, FeO, FeO₂, CrO, Cr₂O₃, CrO₂, MnO, Mn₂O₃, RuO, and combinations thereof.

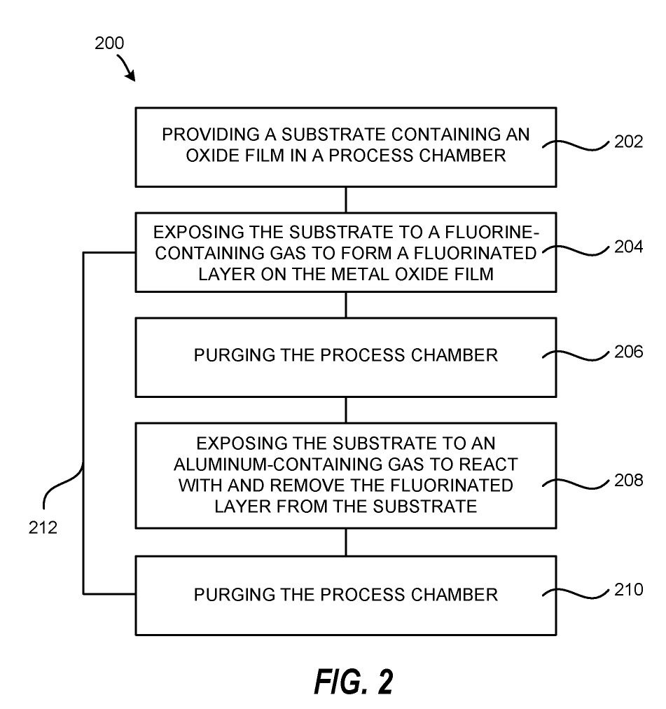

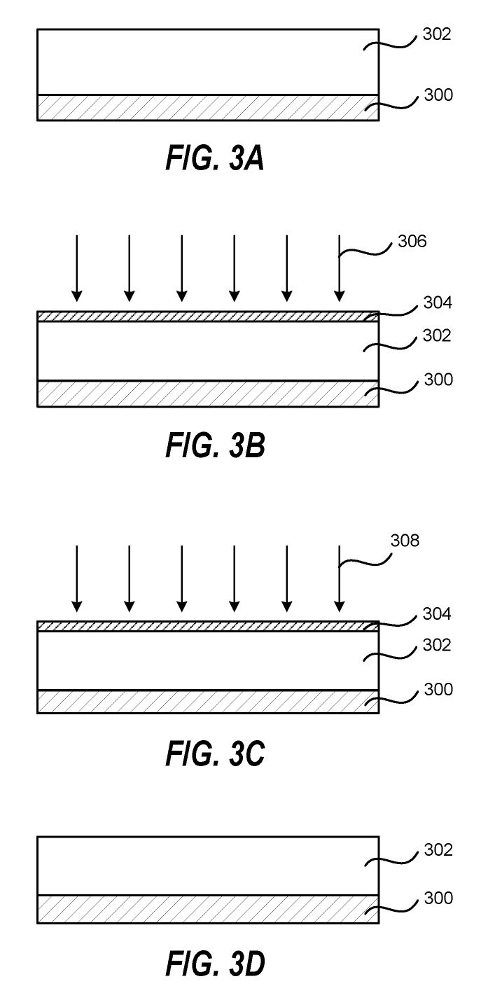

FIG. 2 is a process flow diagram for processing a substrate according to an embodiment of the invention. Referring also to FIGS. 3A-3D, the process flow 200 includes, in 202, providing a substrate 300 containing a metal oxide film 302 in process chamber. For example, the metal oxide film 302 may be selected from the group consisting of Al₂O₃, HfO₂, TiO₂, ZrO₂, Y₂O₃, La₂O₃, UO₂, Lu₂O₃, Ta₂O₅, Nb₂O₅, ZnO, MgO, CaO, BeO, V₂O₅, FeO, FeO₂, CrO, Cr₂O₃, CrO₂, MnO, Mn₂O₃, RuO, and combinations thereof. The substrate 300 may be heated to a temperature between 100° C. and 400° C., for example. In 204, the substrate 300 is exposed to fluorine-containing gas 306 to form a fluorinated layer 304 on the metal oxide film 302. For example, the fluorine-containing gas may be selected from HF and NF₃. In 206, the process chamber may be purged with an inert gas (e.g., argon (Ar) or nitrogen (N₂)) to remove excess fluorine-containing gas and reaction byproducts.

Thereafter, in 208, the substrate 300 is exposed to an aluminum-containing gas 308 to react with and remove the fluorinated layer 304. The reaction byproducts include volatile species that desorb from the substrate 300 and are efficiently pumped out of the process chamber. The aluminum-containing gas can contain an organic aluminum compound. In one example, the aluminum-containing gas may be selected from the group consisting of AlMe₃, AlEt₃, AlMe₂H, [Al(O-s-Bu)₃]₄, Al(CH₃COCHCOCH₃)₃, AlCl₃, AlBr₃, AlI₃, Al(O-i-Pr)₃, [Al(NMe₂)₃]₂, Al(i-Bu)₂Cl, Al(i-Bu)₃, Al(i-Bu)₂H, AlEt₂Cl, Et₃Al₂(O-s-Bu)₃, H₃AlNMe₃, H₃AlNEt₃, H₃AlNMe₂Et, and H₃AlMeEt₂. The metal oxide film may be selected from the group consisting of Al₂O₃, HfO₂, TiO₂, ZrO₂, Y₂O₃, La₂O₃, UO₂, Lu₂O₃, Ta₂O₅, Nb₂O₅, ZnO, MgO, CaO, BeO, V₂O₅, FeO, FeO₂, CrO, Cr₂O₃, CrO₂, MnO, Mn₂O₃, RuO, and combinations thereof.

In 210, the chamber may be purged with an inert gas to remove excess aluminum-containing gas and reaction byproducts. As shown by process arrow 212, the alternating exposures 204-210 may be repeated at least once to further etch the metal oxide film 302. The alternating exposures 204-210 constitute one ALE cycle.

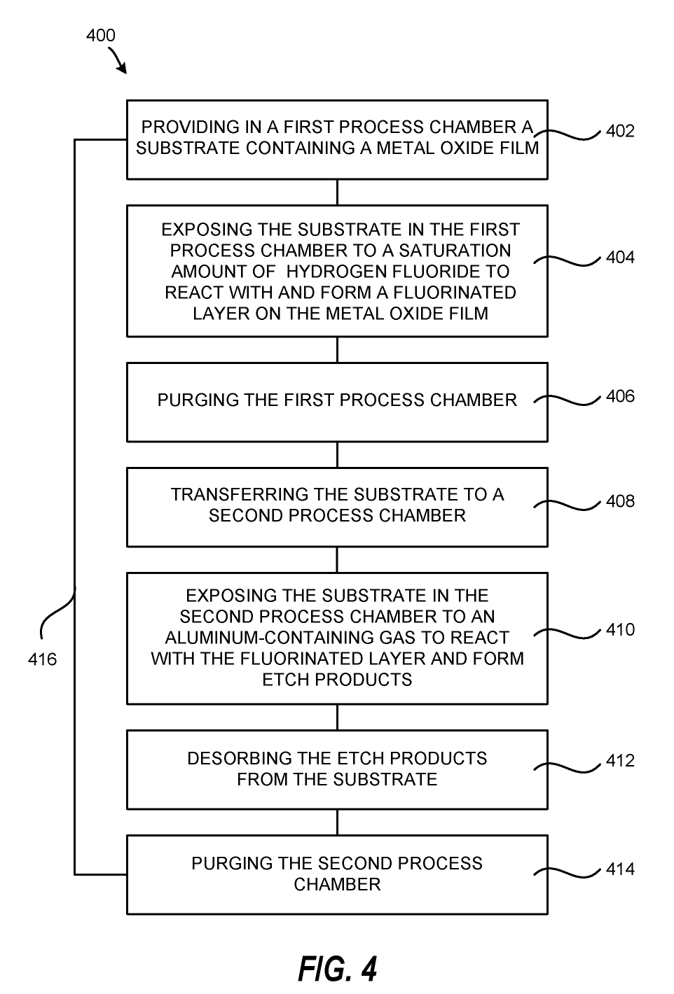

FIG. 4 is a process flow diagram for processing a substrate according to an embodiment of the invention. The process flow 400 includes, in 402, providing in a first process chamber a substrate containing a metal oxide film. For example, the metal oxide film may be selected from the group consisting of Al₂O₃, HfO₂, TiO₂, ZrO₂, Y₂O₃, La₂O₃, UO₂, Lu₂O₃, Ta₂O₅, Nb₂O₅, ZnO, MgO, CaO, BeO, V₂O₅, FeO, FeO₂, CrO, Cr₂O₃, CrO₂, MnO, Mn₂O₃, RuO, and combinations thereof. The substrate may be heated to a temperature between about 20° C. and about 400° C., for example. In 404, the substrate is exposed in the first process chamber to a saturation amount of fluorine-containing gas to react with and form a fluorinated layer on the metal oxide film. For example, the fluorine-containing gas may be selected from HF and NF₃. In 406, the first process chamber may be purged with an inert gas (e.g., Ar or N₂) to remove excess fluorine-containing gas and reaction byproducts.

Thereafter, in 408, the substrate is transferred to a second process chamber for further processing. The substrate may be heated to a temperature between about 100° C. and about 400° C., for example. In 410, the substrate is exposed to an aluminum-containing gas to react with the fluorinated later and form reaction products. The aluminum-containing gas can contain an organic aluminum compound. In one example, the aluminum-containing gas may be selected from the group consisting of AlMe₃, AlEt₃, AlMe₂H, [Al(O-s-Bu)₃]₄, Al(CH₃COCHCOCH₃)₃, AlCl₃, AlBr₃, AlI₃, Al(O-i-Pr)₃, [Al(NMe₂)₃]₂, Al(i-Bu)₂Cl, Al(i-Bu)₃, Al(i-Bu)₂H, AlEt₂Cl, Et₃Al₂(O-s-Bu)₃, H₃AlNMe₃, H₃AlNEt₃, H₃AlNMe₂Et, and H₃AlMeEt₂. In 412, the etch products are desorbed from the substrate. In 414, the second process chamber may be purged with an inert gas (e.g., Ar or N₂) to remove excess aluminum-containing gas and reaction byproducts. As shown by process arrow 416, the processing steps 402-414 may be repeated at least once to further etch the metal oxide film.

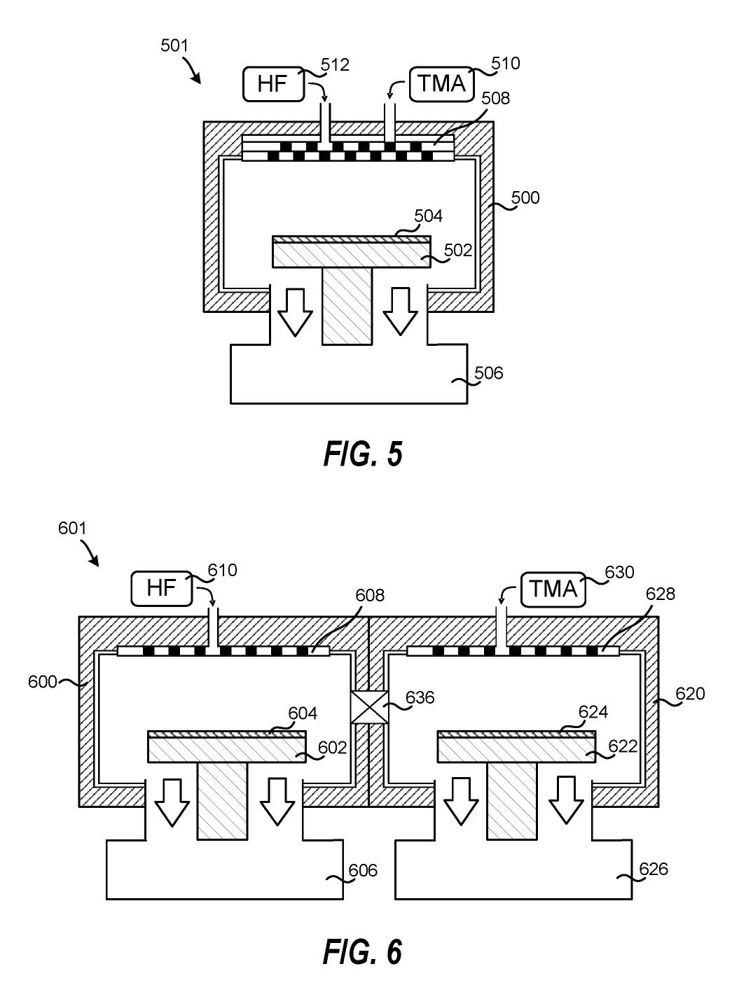

FIG. 5 schematically shows a processing system for processing a substrate according to an embodiment of the invention. The processing system 501 includes a process chamber 500, a substrate holder 502 to support a substrate 504, a pumping system 506 to evacuate the process chamber 500, and a showerhead 508 to deliver gases into the process chamber 500. The substrate 504 may be heated to a temperature between about 20° C. and about 400° C., for example. Gas supply systems 510 and 512 are configured to supply processing gases to the showerhead 508. Although not shown in FIG. 5, the processing system 501 may also be configured for purging the process chamber with an inert gas. The exemplary processing gases in FIG. 5 include a fluorine-containing gas and trimethylaluminum (AlMe₃, TMA) gas. The processing system 501 can be configured to perform the processing steps described in FIG. 2 by alternately exposing the substrate 504 to fluorine-containing gas and an aluminum-containing gas, separated by inert gas purging.

FIG. 6 schematically shows a processing system for processing a substrate according to an embodiment of the invention. The processing system 601 contains a first process chamber 600, a substrate holder 602 to support a substrate 604, a pumping system 606 to evacuate the first process chamber 600, and a showerhead 608 to deliver gases into the first process chamber 600. Gas supply system 610 is configured to supply a fluorine-containing gas to the showerhead 608. The processing system 601 further contains a second process chamber 620, a substrate holder 622 to support a substrate 624, a pumping system 626 to evacuate the second process chamber 620, a gate valve 636 for transferring a substrate under vacuum between the first process chamber 600 and the second process chamber 620, and a showerhead 628 to deliver gases into the second process chamber 620. Gas supply system 630 is configured to supply TMA gas (or another aluminum-containing gas) to the showerhead 628. Although not shown in FIG. 6, the processing system 601 may also be configured for purging the first process chamber 600 and the second process chamber 620 with an inert gas. The processing system 601 can be configured to perform the processing steps described in FIG. 4 where a substrate containing a metal oxide film can be exposed to a fluorine-containing gas in the first process chamber 600, thereafter transferred to the second process chamber 620, and exposed to an aluminum-containing gas. The use of two separate process chambers 600, 620 allows for independent temperature control for substrates 604 and 624, as the steps of exposing a substrate to a saturation amount of the fluorine-containing gas and exposing the substrate to the aluminum-containing gas may be performed at different substrate temperatures.

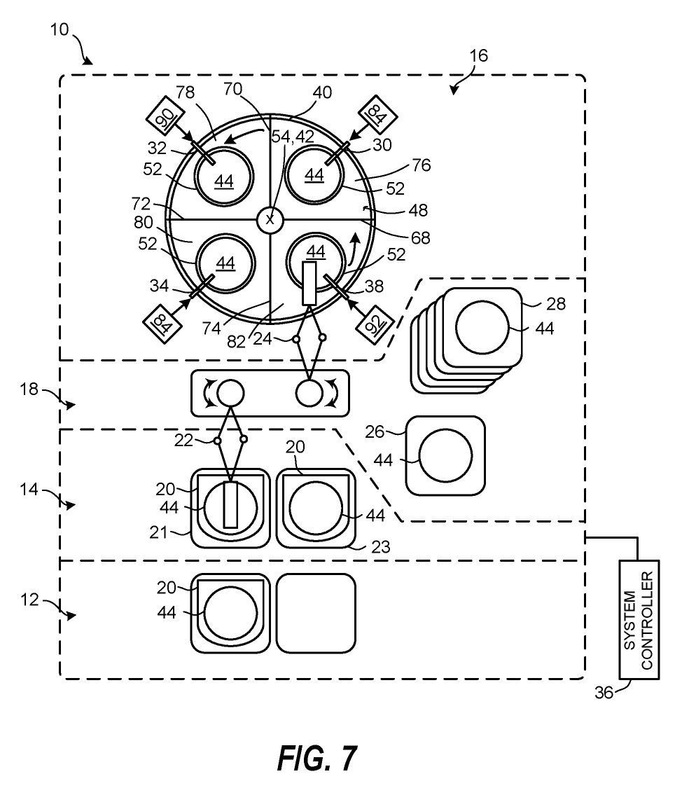

FIG. 7 schematically shows a processing system for processing a substrate according to an embodiment of the invention. A batch processing system 10 for processing a plurality of substrates 44 includes an input/output station 12, a load/lock station 14, a process chamber 16, and a transfer chamber 18 interposed between the load/lock station 14 and process chamber 16. The batch processing system 10, which is shown in a simplified manner, may include additional structures, such as additional vacuum-isolation walls coupling the load/lock station 14 with the transfer chamber 18 and the process chamber 16 with the transfer chamber 18, as understood by a person having ordinary skill in the art. The input/output station 12, which is at or near atmospheric pressure, is adapted to receive wafer cassettes 20, such as front opening unified pods (FOUPs). The wafer cassettes 20 are sized and shaped to hold a plurality of substrates 44, such as semiconductor wafers having diameters of, for example, 200 or 300 millimeters.

The load/lock station 14 is adapted to be evacuated from atmospheric pressure to a vacuum pressure and to be vented from vacuum pressure to atmospheric pressure, while the process chamber 16 and transfer chamber 18 are isolated and maintained continuously under vacuum pressures. The load/lock station 14 holds a plurality of the wafer cassettes 20 introduced from the atmospheric pressure environment of the input/output station 12. The load/lock station 14 includes platforms 21, 23 that each support one of the wafer cassettes 20 and that can be vertically indexed to promote wafer transfers to and from the process chamber 16.

A wafer transfer mechanism 22 transfers substrates 44 under vacuum from one of the wafer cassettes 20 in the load/lock station 14 through the transfer chamber 18 and into the process chamber 16. Another wafer transfer mechanism 24 transfers substrates 44 processed in the process chamber 16 under vacuum from the process chamber 16 through the transfer chamber 18 and to the wafer cassettes 20. The wafer transfer mechanisms 22, 24, which operate independently of each other for enhancing the throughput of the batch processing system 10, may be selective compliant articulated/assembly robot arm (SCARA) robots commonly used for pick-and-place operations. The wafer transfer mechanisms 22, 24 include end effectors configured to secure the substrates 44 during transfers. The process chamber 16 may include distinct first and second sealable ports (not shown) used by wafer transfer mechanisms 22, 24, respectively, to access processing spaces inside the process chamber 16. The access ports are sealed when a deposition or etch process is occurring in the process chamber 16. Wafer transfer mechanism 22 is depicted in FIG. 7 as transferring unprocessed substrates 44 from wafer cassettes 20 on platform 21 of the load/lock station 14 to the process chamber 16. Wafer transfer mechanism 24 is depicted in FIG. 7 as transferring processed substrates 44 from the process chamber 16 to wafer cassettes 20 on platform 23 of the load/lock station 14.

The wafer transfer mechanism 24 may also transfer processed substrates 44 extracted from the process chamber 16 to a metrology station 26 for examination or to a cool down station 28 used for post-processing low pressure cooling of the substrates 44. The processes performed in the metrology station 26 may include, but are not limited to, conventional techniques used to measure film thickness and/or film composition, such as ellipsometry, and particle measurement techniques for contamination control.

The batch processing system 10 is equipped with a system controller 36 programmed to control and orchestrate the operation of the batch processing system 10. The system controller 36 typically includes a central processing unit (CPU) for controlling various system functions, chamber processes and support hardware (e.g., detectors, robots, motors, gas sources hardware, etc.) and monitoring the system and chamber processes (e.g., chamber temperature, process sequence throughput, chamber process time, input/output signals, etc.). Software instructions and data can be coded and stored within the memory for instructing the CPU. A software program executable by the system controller 36 determines which tasks are executed on substrates 44 including tasks relating to monitoring and execution of the processing sequence tasks and various chamber process recipe steps.

A susceptor 48 is disposed inside the process chamber 16. The susceptor 48 includes a plurality of circular substrate supports 52 defined in a top surface of the susceptor 48. Each of the substrate supports 52 is configured to hold at least one of the substrates 44 at a location radially within the peripheral sidewall 40 of the process chamber 16. The number of individual substrate supports 52 may range, for example, from 2 to 8. However, a person having ordinary skill in the art would appreciate that the susceptor 48 may be configured with any desired number of substrate supports 52 depending on the dimensions of the substrates 44 and the dimensions of the susceptor 48. Although this embodiment of the invention is depicted as having substrate supports 52 of a circular or round geometrical shape, one of ordinary skill in the art would appreciate that the substrate supports 52 may be of any desired shape to accommodate an appropriately shaped substrate.

The batch processing system 10 may be configured to process 200 mm substrates, 300 mm substrates, or larger-sized round substrates, which dimensioning will be reflected in the dimensions of substrate supports 52. In fact, it is contemplated that the batch processing system 10 may be configured to process substrates, wafers, or liquid crystal displays regardless of their size, as would be appreciated by those skilled in the art. Therefore, while aspects of the invention will be described in connection with the processing of substrates 44 that are semiconductor substrates, the invention is not so limited.

The substrate supports 52 are distributed circumferentially on the susceptor 48 about a uniform radius centered on an axis of rotation 54. The substrate supports 52 have approximately equiangular spacing about the axis of rotation 54, which is substantially collinear or coaxial with the azimuthal axis 42 although the invention is not so limited.

When the substrates 44 are processed in the process chamber 16, the rotation of the susceptor 48 may be continuous and may occur at a constant angular velocity about the axis of rotation 54. Alternatively, the angular velocity may be varied contingent upon the angular orientation of the susceptor 48 relative to an arbitrary reference point.

Partitions 68, 70, 72, 74 compartmentalize the process chamber 16 into a plurality of processing spaces 76, 78, 80, 82, while allowing the susceptor 48 and the substrate supports 52 to freely rotate around the axis of rotation 54. The partitions 68, 70, 72, 74 extend radially relative to the axis of rotation 54 toward the peripheral sidewall 40. Although four partitions 68, 70, 72, 74 are representatively shown, a person having ordinary skill in the art would appreciate that the process chamber 16 may be subdivided with any suitable plurality of partitions to form a different number than four processing spaces.

The batch processing system 10 further includes a purge gas supply system 84 coupled by gas lines to gas injectors 30, 34 penetrating through the peripheral sidewall 40. The purge gas supply system 84 is configured to introduce a flow of a purge gas to processing spaces 76 and 80. The purge gas introduced into the processing spaces 76 and 80 can comprise an inert gas, such as a noble gas (i.e., helium, neon, argon, xenon, krypton), or nitrogen, or hydrogen. During substrate processing, purge gas is continuously introduced into the processing spaces 76 and 80 to provide a gaseous curtain or barrier preventing, or at the least significantly limiting, transfer of first and second process gases between processing spaces 78, 82. The purge gas also provides an inert atmosphere inside processing spaces 76, 80 so that any thin films carried by the substrates 44 are substantially unchanged when transported on the susceptor 48 through processing spaces 76, 80. Processing space 78 is juxtaposed between processing spaces 76, 80 and processing space 82 is juxtaposed between processing spaces 76, 80 so that processing spaces 76, 80 separate processing spaces 78 and 82 to provide mutual isolation for the first and second process gases.

Batch processing system 10 further includes a first process gas supply system 90 coupled by gas lines to gas injector 32 penetrating through the peripheral sidewall 40, and a second gas supply system 92 coupled by gas lines to gas injector 38 penetrating through the peripheral sidewall 40. The first process gas supply system 90 is configured to introduce a first process gas to processing space 78, and the second gas supply system 92 configured to introduce a second process gas to processing space 82. The first and second gas supply systems 90, 92 may each include one or more material sources, one or more heaters, one or more pressure control devices, one or more flow control devices, one or more filters, one or more valves, or one or more flow sensors as conventionally found in such gas supply systems.

The first process gas can, for example, comprise a fluorine-containing gas (e.g., HF gas or NF₃ gas), and it may be delivered to processing space 78 either with or without the assistance of a carrier gas. The second process gas can, for example, comprises an aluminum-containing gas, and it may be delivered to processing space 82 either with or without the assistance of a carrier gas.

The first process gas is supplied by the first process gas supply system 90 to process chamber 16 and the second process gas is supplied by the second process gas supply system 92 to process chamber 16 are selected in accordance with the composition and characteristics of a film to be etched by ALE on the substrate. According to one embodiment, one or more of the first process gas supply system 90, the second process gas supply system 92, and the purge gas supply system 84 may be further configured for injecting a purge gas into one or more of the processing spaces 76, 78, 80, 82.

When the susceptor 48 is rotated about the axis of rotation 54, the arrangement of the substrate supports 52 about the circumference of the susceptor 48 allows each substrate 44 to be sequentially exposed to the different environment inside each of the processing spaces 76, 78, 80, 82. By way of example, upon rotation of the susceptor 48 through a closed path of 2π radians (360°), each of the substrates 44 is serially exposed to first process gas in the environment inside the first processing space 78, then to the purge gas comprising the environment inside the second processing space 80, then to the second process gas in the environment inside the third processing space 82, and finally to the purge gas comprising the environment inside the fourth processing space 76. Each of the substrates 44 has a desired dwell time in each of the respective processing spaces 76, 78, 80, 82, as mandated by the characteristics of the film to be deposited on each of the substrates 44, sufficient to form etch the metal oxide film.

In the ALE process, etching of the metal oxide film on the substrates 44 is controlled by alternating and sequential introduction of appropriate process gases that react in a self-limiting manner to incrementally etch the metal oxide film. Within the first processing space 78, molecules of the first process gas bond (chemically, by absorption, by adsorption, etc.) to the top surface of each of the substrates 44 to form a monolayer or a fraction of a monolayer of the first process gas. Within the third processing space 82, the second process gas reacts with the molecules of the first process gas on each successive substrate 44. As the substrates 44 are rotated through the first and third processing spaces 78, 82, these steps are repeated with sequential subsequent exposures to the first and second process gases. The environments of first and second process gases in the first and third processing spaces 78, 82, respectively, are isolated from each other by the chemically non-reactive, purge gas environments inside the second and fourth processing spaces 80, 76. The substrates 44 may be heated to a process temperature to thermally promote the ALE process. The process temperature can be between about 20° C. and about 400° C., for example.

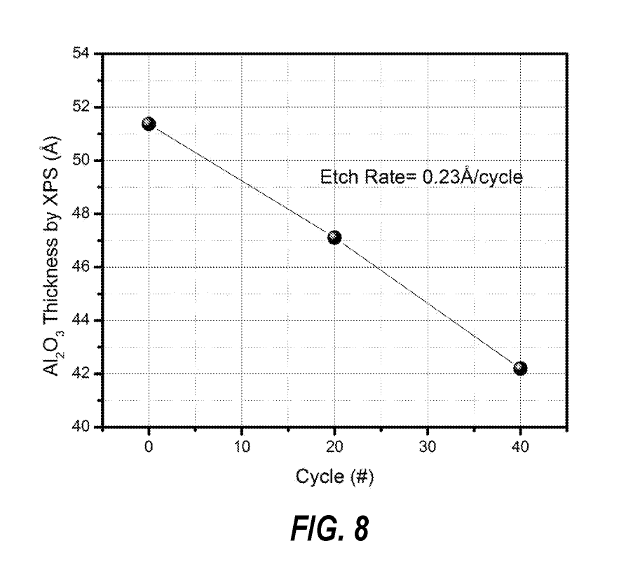

FIG. 8 shows etching of Al₂O₃ films by ALE according to an embodiment of the invention. The etching was performed using alternating exposures of HF and TMA in the absence of a plasma at a substrate temperature of approximately 100° C. Argon purges were used to purge the process chamber between HF and TMA exposures in each ALE cycle. The etch rate of the Al₂O₃ films was about 0.23 Angstrom/ALE cycle.

A plurality of embodiments for atomic layer etching using a fluorine-containing gas and an aluminum-containing gas have been described. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. It is therefore intended that the scope of the invention be limited not by this detailed description, but rather by the claims appended hereto.

What is claimed is:

1. A method of atomic layer etching (ALE), the method comprising:
providing a substrate; and
alternatingly exposing the substrate to a fluorine-containing gas and an aluminum-containing gas to etch the substrate.

2. The method of claim 1, wherein the alternating exposures are repeated at least once to further etch the substrate.

3. The method of claim 1, wherein the substrate contains a metal oxide film that is etched by the alternating exposures.

4. The method of claim 1, wherein the metal oxide film is selected from the group consisting of Al₂O₃, HfO₂, TiO₂, ZrO₂, Y₂O₃, La₂O₃, UO₂, Lu₂O₃, Ta₂O₅, Nb₂O₅, ZnO, MgO, CaO, BeO, V₂O₅, FeO, FeO₂, CrO, Cr₂O₃, CrO₂, MnO, Mn₂O₃, RuO, and combinations thereof.

5. The method of claim 1, wherein the fluorine-containing gas contains hydrogen fluoride (HF) or nitrogen trifluoride (NF₃).

6. The method of claim 1, wherein the aluminum-containing gas contains an organic aluminum compound.

7. The method of claim 1, wherein the aluminum-containing gas contains an aluminum alkyl compound.

8. The method of claim 1, wherein the aluminum-containing gas is selected from the group consisting of AlMe₃, AlEt₃, AlMe₂H, [Al(O-s-Bu)₃]₄, Al(CH₃COCHCOCH₃)₃, AlCl₃, AlBr₃, AlI₃, Al(O-i-Pr)₃, [Al(NMe₂)₃]₂, Al(i-Bu)₂Cl, Al(i-Bu)₃, Al(i-Bu)₂H, AlEt₂Cl, Et₃Al₂(O-s-Bu)₃, H₃AlNMe₃, H₃AlNEt₃, H₃AlNMe₂Et, and H₃AlMea₂.

9. The method of claim 1, wherein the fluorine-containing gas contains hydrogen fluoride (HF) and the aluminum-containing gas contains trimethyl aluminum (AlMe₃).

10. A method of atomic layer etching (ALE), the method comprising:
providing a substrate containing a metal oxide film;
exposing the substrate to a fluorine-containing gas to form a fluorinated layer on the metal oxide film; and
thereafter, exposing the substrate to an aluminum-containing gas to remove the fluorinated layer from the metal oxide film.

11. The method of claim 10, wherein the exposing steps are alternatingly repeated at least once to further etch the metal oxide film.

12. The method of claim 10, wherein the metal oxide film is selected from the group consisting of Al₂O₃, HfO₂, TiO₂, ZrO₂, Y₂O₃, La₂O₃, UO₂, Lu₂O₃, Ta₂O₅, Nb₂O₅, ZnO, MgO, CaO, BeO, V₂O₅, FeO, FeO₂, CrO, Cr₂O₃, CrO₂, MnO, Mn₂O₃, RuO, and combinations thereof.

13. The method of claim 9, wherein the fluorine-containing gas contains hydrogen fluoride (HF) or nitrogen trifluoride (NF₃).

14. The method of claim 10, wherein the aluminum-containing gas is selected from the group consisting of AlMe₃, AlEt₃, AlMe₂H, [Al(O-s-Bu)₃]₄, Al(CH₃COCHCOCH₃)₃, AlCl₃, AlBr₃, AlI₃, Al(O-i-Pr)₃, [Al(NMe₂)₃]₂, Al(i-Bu)₂Cl, Al(i-Bu)₃, Al(i-Bu)₂H, AlEt₂Cl, Et₃Al₂(O-s-Bu)₃, H₃AlNMe₃, H₃AlNEt₃, H₃AlNMe₂Et, and H₃AlMeEt₂.

15. The method of claim 10, further comprising gas purging with an inert gas between the exposing steps.

16. The method of claim 10, wherein the exposing steps are performed in the same process chamber.

17. A method of atomic layer etching (ALE), the method comprising:
providing in a first process chamber a substrate containing a metal oxide film;
exposing the substrate in the first process chamber to a saturation amount of a fluorine-containing gas to form a fluorinated layer on the metal oxide film;
transferring the substrate to a second process chamber;
exposing the substrate in the second process chamber to an aluminum-containing gas to react with the fluorinated layer and form etch products; and
desorbing the etch products from the substrate,
wherein the exposing steps are alternatingly repeated at least once to further etch the metal oxide film.

18. The method of claim 17, wherein the fluorine-containing gas contains hydrogen fluoride (HF) or nitrogen trifluoride (NF₃), and wherein the aluminum-containing gas is selected from the group consisting of AlMe₃, AlEt₃, AlMe₂H, [Al(O-s-Bu)₃]₄, Al(CH₃COCHCOCH₃)₃, AlCl₃, AlBr₃, AlI₃, Al(O-i-Pr)₃, [Al(NMe₂)₃]₂, Al(i-Bu)₂Cl, Al(i-Bu)₃, Al(i-Bu)₂H, AlEt₂Cl, Et₃Al₂(O-s-Bu)₃, H₃AlNMe₃, H₃AlNEt₃, H₃AlNMe₂Et, and H₃AlMeEt₂.

19. A method atomic layer etching (ALE), the method comprising:
arranging substrates containing a metal oxide film on a plurality of substrate supports in a process chamber, wherein the process chamber contains processing spaces defined around an axis of rotation in the process chamber;
rotating the plurality of substrate supports about the axis of rotation;
exposing the substrates in a first processing space a fluorine-containing gas to form a fluorinated layer on the metal oxide film, the first processing space defined by a first included angle about the axis of rotation;
exposing the substrates to an inert atmosphere within a second processing space defined by a second included angle about the axis of rotation;
exposing the substrates in a third processing space to an aluminum-containing gas to remove the fluorinated layer from the metal oxide film, the third processing space defined by a third included angle about the axis of rotation and separated from the first processing space by the second processing space;
exposing the substrates to an inert atmosphere within a fourth processing space defined by a fourth included angle about the axis of rotation and separated from the second processing space by the third processing space; and
re-exposing the substrates to the fluorine-containing gas and the aluminum-containing gas by repeatedly rotating the substrates through the first, second, third, and fourth processing spaces for incrementally etching the metal oxide film on each of the substrates.

20. The method of claim 19, wherein the fluorine-containing gas contains hydrogen fluoride (HF) or nitrogen trifluoride (NF₃), and wherein the aluminum-containing gas is selected from the group consisting of AlMe₃, AlEt₃, AlMe₂H, [Al(O-s-Bu)₃]₄, Al(CH₃COCHCOCH₃)₃, AlCl₃, AlBr₃, AlI₃, Al(O-i-Pr)₃, [Al(NMe₂)₃]₂, Al(i-Bu)₂Cl, Al(i-Bu)₃, Al(i-Bu)₂H, AlEt₂Cl, Et₃Al₂(O-s-Bu)₃, H₃AlNMe₃, H₃AlNEt₃, H₃AlNMe₂Et, and H₃AlMeEt₂.
